(19) United States
(12) Patent Application Publication
(10) Pub. No.: US 2010/0300512 A1
(43) Pub. Date: Dec. 2, 2010

(54) MADE TO ELEMENTS CAPABLE OF COLLECTING LIGHT

(75) Inventors: Stephane Auvray, Suresnes (FR); Delphine Dupuy, Massy (FR); Nikolas Janke, Herzogenrath (DE)

Correspondence Address: OBLON, SPIVAK, MCCLELLAND MAIER & NEUSTADT, L.L.P., 1940 DUKE STREET, ALEXANDRIA, VA, 22314, US

(73) Assignee: SAINT-GOBAIN GLASS FRANCE, COURBEVOIE (FR)

(21) Appl. No.: 12/746,677

(22) PCT Filed: Dec. 2, 2008
(86) PCT No.: PCT/FR08/52187

§ 371 Date: Aug. 19, 2010

(30) Foreign Application Priority Data
Dec. 7, 2007 (FR) 0759632

(51) Int. Cl. H01L 31/04; C23C 14/34

(52) U.S. Cl. 136/252; 204/192.12

(57) ABSTRACT

A substrate having a glass function, comprising a main face intended to be combined with a layer based on an absorbent material, characterized in that it comprises, on at least one surface portion of the main face, at least one electrode that reflects in the wavelength range extending from the ultraviolet to the near infrared, said electrode being formed from a stack of n layers (where n≧2) defining between them interface zones.

The present invention relates to improvements made to elements capable of collecting light or more generally to any electronic device such as a solar cell based on semiconductor materials.

It is known that elements capable of collecting light of the thin-film photovoltaic solar cell type comprise a layer of absorbent agent, at least one electrode placed on the side on which the light is incident, based on an electrically conductive material, and a rear electrode based on a material that is also conductive, it being possible for this rear electrode to be relatively thick and opaque. It must be essentially characterized by an electrical surface resistance as low as possible and good adhesion to the absorber layer and, where appropriate, to the substrate.

Chalcopyrite ternary compounds that can act as an absorber generally contain copper, indium and selenium.

Layers of such absorbent agents are then referred to as CISe₂ layers. The layer of absorbent agent may also contain gallium (e.g. Cu(In,Ga)Se₂ or CuGaSe₂), aluminum (e.g. Cu(In,Al)Se₂), or sulfur (e.g. CuIn(Se,S). They are denoted in general, and hereafter, by the term “chalcopyrite absorbent agent layers”.

In the context of this chalcopyrite absorbent agent system, the rear electrodes manufactured are usually based on a conductive material, such as for example molybdenum.

Now, high performance in this system can be achieved only by rigorously controlling the crystalline growth of the absorbent agent layer and its chemical composition.

In addition, it is known that among all the factors contributing thereto, the presence of sodium (Na) on the layer of Mo is a key parameter that promotes the crystallization of chalcopyrite absorbent agents. Its presence in a controlled amount enables the density of defects in the absorber to be reduced and increases its conductivity.

The substrate having a glass function, which contains alkali metals, generally based on soda-lime-silica glass, naturally constitutes a sodium reservoir. Under the effect of the process for manufacturing the layers of the absorbent agent, generally carried out at high temperature, the alkali metals migrate through the substrate, and through the molybdenum-based rear electrode, into the layer of absorbent agent, especially of the chalcopyrite type. The molybdenum layer allows the sodium from the substrate to diffuse freely into the upper active layers under the effect of a thermal annealing operation. This Mo layer has, despite everything, the drawback of allowing only partial and not very precise control of the amount of Na that migrates to the Mo/CIGSe₂ interface.

According to one variant embodiment, the layer of absorbent agent is deposited at high temperature on the molybdenum-based layer, which is separated from the substrate by means of a barrier layer based on silicon nitrides, oxides or oxynitrides, or based on aluminum oxides or oxynitrides or based on titanium or zirconium nitride. This barrier layer prevents the sodium, arising from the diffusion within the substrate, from diffusing into the upper active layers deposited on the Mo.

Although adding an additional step to the manufacturing process, the latter solution offers the possibility of very precisely metering the amount of Na deposited on the Mo layer by employing an external source (e.g. NaF, Na₂O₂ or Na₂Se).

Other absorbent agent families, in thin-film form, may be used in elements capable of collecting light. In particular, those based on silicon are known, the silicon possibly being amorphous or microcrystalline or even crystalline, or those based on cadmium telluride (CdTe).

There is also another family of absorbent agents based on single-crystal or polycrystalline silicon wafers in thick-film form, with a thickness of between 50 μm and 250 μm.

Whatever the family of absorbent agents, it is always found that the energy conversion efficiency is higher when the amount of light energy covering the largest part of the solar spectrum, namely from the ultraviolet to the near infrared passing through the wavelength range of the visible, is absorbed by the absorbent agent so as to be converted into electrical energy. Starting from this observation, photovoltaic cell manufacturers seek to trap the maximum amount of light radiation within the cell, including reflecting the slightest radiation not absorbed, that is to say that reflected toward the absorbent agent.

Within this search to optimize the energy conversion, the inventors have surprisingly and unexpectedly discovered that the structure of the electrode in contact with the layer of absorbent agent plays a paramount role.

The aim of the present invention is therefore to alleviate these drawbacks by proposing an improved electrode that maximizes radiation incident on the absorbent agent.

For this purpose, the substrate having a glass function, comprising a main face intended to be combined with a layer based on an absorbent material, is characterized in that it comprises, on at least one surface portion of the main face, at least one electrically conductive electrode that reflects in the wavelength range extending from the ultraviolet to the near infrared, said electrode being formed from a stack of n layers (where n 2) defining between them interface zones.

Thanks to the presence of interface zones between the layers forming the electrode, refractive index jumps are created at each interface, which improve the reflection of incident radiation onto the absorbent agent.

In preferred embodiments of the invention, one and/or another of the following arrangements may optionally be furthermore employed:
the electrode is based on a conductive material chosen from silver, molybdenum, copper, aluminum, nickel, chromium, nickel-chromium and tantalum or based on a nitride of conductive materials chosen from molybdenum, titanium, niobium, zirconium and tantalum;
the electrode is based on molybdenum at most 500 nm, especially at most 400 nm or at most 300 nm or at most 200 nm in thickness;
the electrode comprises between 1 and 16 layers, preferably between 4 and 12 layers and more preferably close to 8 layers;
each of the layers forming the electrode comprises an identical material;
each of the layers forming the electrode possesses an approximately identical thickness;
the layers forming the electrode are formed from different materials;
it includes, over at least one surface portion of the main face, at least one alkali barrier layer, the electrode being deposited on said barrier layer;
the barrier layer is based on a dielectric material;
the dielectric material is based on silicon nitrides, oxides or oxynitrides, or on aluminum nitrides, oxides or oxynitrides, or on titanium or zirconium nitride, these being used alone or in a mixture;
the thickness of the barrier layer is between 3 and 200 nm, preferably between 20 and 150 nm and substantially close to 130 nm;
the barrier layer is based on silicon nitride;
the layer based on silicon nitride is substoichiometric; and
the layer based on silicon nitride is superstoichiometric.

According to another aspect of the invention, it also relates to an element capable of collecting light using at least one substrate as defined above.

In preferred embodiments of the invention, one or more of the following arrangements may optionally be furthermore employed:
element capable of collecting light, comprising a first substrate having a support function and a second substrate having a glass function, said substrates sandwiching, between two conductive layers forming the electrodes, at least one functional layer based on an absorbent agent enabling light energy to be converted to electrical energy, characterized in that at least one of the electrodes is reflecting in the wavelength range extending from the ultraviolet to the near infrared, said electrode being formed from a stack of n layers (where n≧2) defining between them interface zones.

Further features, details and advantages of the present invention will become more clearly apparent on reading the following description, given by way of entirely nonlimiting illustration and with reference to the appended drawings in which:

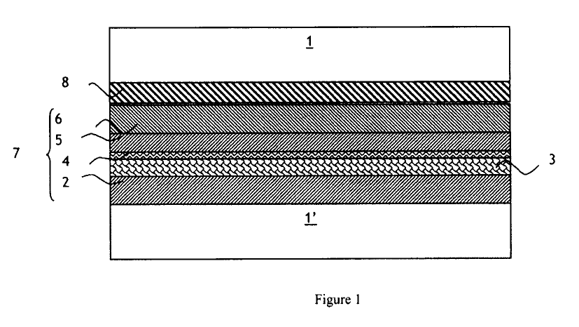

FIG. 1 is a schematic view of an element capable of collecting light according to the invention;

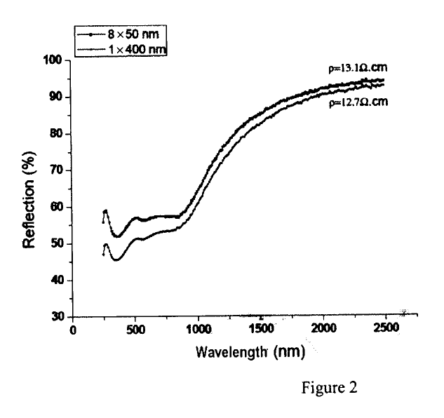

FIG. 2 is a graph showing the variation in reflectivity as a function of the number of layers constituting the electrode, for a constant layer thickness; and

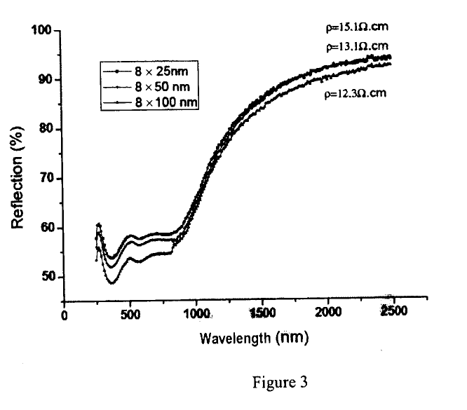

FIG. 3 is a graph showing the variation in reflectivity as a function of the number of layers constituting the electrode, at a constant number of layers.

FIG. 1 shows an element capable of collecting light (a solar or photovoltaic cell).

The transparent substrate 1 having a glass function may for example be made entirely of glass containing alkali metals such as soda-lime-silica glass. It may also be made of a thermoplastic polymer, such as a polyurethane or a polycarbonate or a polymethylmethacrylate.

Essentially all of the mass (i.e. at least 98% by weight) or even all of the substrate having a glass function is made up of one or more materials having the best possible transparency and preferably having a linear absorption of less than 0.01 mm⁻¹ in that part of the spectrum useful for the application (solar module), generally the spectrum ranging from the ultraviolet (about 280 nm) to the near infrared (substantially close to 1200 nm).

The substrate 1 according to the invention may have a total thickness ranging from 0.5 to 10 mm when used as protective plate for a photovoltaic cell based on various chalcopyrite technologies (CIS, CIGS, CIGSe₂, etc.) or as support substrate 1′ intended for receiving the entire functional multilayer stack. When the substrate 1 is used as a protective plate, it may be advantageous to subject this plate to a heat treatment (of the toughening type for example) when it is made of glass.

Conventionally, the front face of the substrate directed toward the light rays is defined as face A (this is the external face) and the rear face of the substrate directed toward the rest of the layers of the solar module is defined as the B face (which is the internal face).

The B face of substrate 1′ is coated with a conductive first layer 2 that has to serve as an electrode. The functional layer 3 based on a chalcopyrite absorbent agent is deposited on this electrode 2. When the functional layer 3 is based for example on CIS, CIGS or CIGSe₂, it is preferable for the interface between the functional layer 3 and the electrode 2 to be based on molybdenum. A conductive layer meeting these requirements is described in European Patent Application EP 1 356 528.

According to one advantageous feature of the invention, the molybdenum electrode is in fact made up of a stack of n layers (n≧2) each consisting of an identical material or of different materials.

As may be seen in the graph of FIG. 2, which shows the variation in reflectivity over the entire spectrum as a function of the number of layers constituting the molybdenum-based electrode. For the same molybdenum thickness, it is found that the more layers in the stack, the higher the reflectivity.

It is also found that the increase in reflectivity (desired effect) is proportional to the number of layers constituting the electrode but also results in an increase in the resistivity (undesired effect).

It may also be seen, based on FIG. 3, which shows the variation in reflectivity over the entire spectrum as a function of the underlayer thickness, that it is preferable to have an electrode preferentially with small underlayer thickness in order to maximize the reflectivity to the detriment of the resistivity.

By combining the two graphs of FIGS. 2 and 3, it can be seen that a compromise may be found for a multilayer stack with n equal to 8 (for a total molybdenum layer thickness of 400 nm).

Since the molybdenum-based electrode becomes more reflective compared with a conventional electrode having a smaller number of layers, the surplus of reflected photons helps to increase the efficiency of the cells. It is also possible to reduce the thickness of the absorber layer while still maintaining a similar efficiency.

The layer 3 of chalcopyrite absorbent agent is coated with a thin layer 4 of cadmium sulfide (CdS) making it possible to create, with the chalcopyrite layer 3, a p-n junction. Specifically, the chalcopyrite agent is generally p-doped, the CdS layer 4 being n-doped, thereby creating the p-n junction needed to establish an electric current.

This thin CdS layer 4 is itself covered with a tie layer 5 generally formed from what is called intrinsic zinc oxide (i:ZnO).

To form the second electrode, the i:ZnO layer 5 is covered with a layer 6 made of a TCO (transparent conductive oxide). This may be chosen from the following materials: doped tin oxide, especially one doped with fluorine or with antimony (the precursors that can be used in the case of deposition by CVD may be tin organometallics or halides associated with a fluorine precursor of the hydrofluoric acid or trifluoroacetic acid type); doped zinc oxide, especially one doped with aluminum or boron (the precursors that can be used in the case of deposition by CVD may be zinc and aluminum organometallics or halides); or else doped indium oxide, especially doped with tin (the precursors that can be used in the case of deposition by CVD may be tin and indium organometallics or halides). This conductive layer must be as transparent as possible and have a high light transmission through all the wavelengths corresponding to the absorption spectrum of the material constituting the functional layer, so as not to unnecessarily reduce the efficiency of the solar module.

It has been found that the relatively thin (for example 100 nm) layer 5 of dielectric ZnO (i:ZnO) between the functional layer 3 and the n-doped conductive layer, for example made of CdS, has a positive influence on the stability of the process for depositing the functional layer.

The conductive layer 6 has a resistance per square of at most 30 ohms/□, especially at most 20 ohms/□ and preferably at most 10 or 15 ohms/□. It is generally between 5 and 12 ohms/□.

The thin-film multilayer stack 7 is sandwiched between two substrates 1 and 1′ via a lamination interlayer 8, for example made of PU, PVB or EVA. The substrate 1′ is distinguished from the substrate 1 by the fact that it is made of glass, based on alkali metals, such as a soda-lime-silica glass or a glass having a low sodium content so as to conform a solar or photovoltaic cell, and is then peripherally encapsulated by means of a gasket or a sealing resin. One example of the composition of this resin and of its means of implementation is described in the application EP 739 042.

According to one feature of the invention, prior to depositing the electrode 2, especially one based on molybdenum, an alkali barrier layer 9 is deposited on all or part of the face of the substrate 1′. This alkali barrier layer 9 is based on a dielectric material, this dielectric material being based on silicon nitrides, oxides or oxynitrides or on aluminum nitrides, oxides or oxynitrides or on titanium or zirconium nitrides, these being used alone or in a mixture. The thickness of the barrier layer is between 3 and 200 nm, preferably between 20 and 150 nm and substantially close to 130 nm.

In this case, the Na content of the glass has only a very low impact owing to the presence of the barrier. A glass of the soda-lime type will be preferably used for economic reasons, but a glass having a low Na content or one of the borosilicate type may also be used.

This alkali barrier layer, for example based on silicon nitride, need not be stoichiometric. It may be substoichiometric naturally, or even, and preferably, superstoichiometric. For example, this layer is made of SiₓN_{y}, with an x/y ratio of at least 0.76, preferably between 0.80 and 0.90, as it has been demonstrated that when the SiₓN_{y} is rich in Si, the alkali barrier effect is all the more effective.

The stoichiometry may for example be adjusted by varying the nitrogen pressure in the sputtering chamber during the deposition of the layers by the reactive magnetron sputtering of a metal target.

The barrier layer 9 is deposited, before the deposition of the molybdenum-based multilayer stacks, by magnetron sputtering of the “sputter down” or “sputter up” type. One example of this production process is given for example in patent EP 1 179 516. The barrier layer may also be deposited by CVD processes, such as PE-CVD.

Among all the possible combinations, the simplest solution is a single-step process, all the layers being deposited in the same coater (i.e. the magnetron sputtering apparatus).

A solar module as described above must, in order to be able to operate and deliver an electrical voltage to an electrical distribution network, be provided, on the one hand, with electrical connection devices and, on the other hand, with support and fastening means so as to ensure that it is oriented with respect to the light radiation.

1. A substrate, comprising a main face comprising an absorbent material layer wherein the substrate comprises, on at least one surface portion of the main face, at least one electrically conductive electrode that reflects in the wavelength range extending from the ultraviolet to the near infrared, said electrode being formed from a stack of n layers (where n≧2) defining between them at least one interface zone, and comprising between 2 and 16 layers.

2. The substrate according to claim 1, wherein the electrode comprises:
a conductive selected from the group consisting of silver, molybdenum, copper, aluminum, nickel, chromium, nickel-chromium and tantalum; or
a nitride of at least one conductive material selected from the group consisting of molybdenum, titanium, niobium, zirconium and tantalum.

3. The substrate according to claim 1, wherein the electrode comprises molybdenum at most 500 nm, in thickness.

4. The substrate according to claim 1, wherein each of the layers forming the electrode comprises an identical material.

5. The substrate according to claim 1, wherein each of the layers forming the electrode possesses an approximately identical thickness.

6. The substrate according to claim 1, wherein the layers forming the electrode are formed from different materials.

7. The substrate according to claim 1, comprising, over at least one surface portion of the main face, at least one alkali barrier layer, the electrode deposited on at least one alkali said barrier layer.

8. The substrate according to claim 7, wherein the barrier layer comprises a dielectric material.

9. The substrate according to claim 8, wherein the dielectric material comprises at least one selected from the group consisting of silicon nitride, oxide or oxynitride, aluminum nitride, oxide or oxynitride, and titanium nitride, and zirconium nitride.

10. The substrate according to claim 7, wherein the thickness of the barrier layer is between 3 and 200 nm.

11. The substrate according to claim 7, wherein the barrier layer is based on comprises silicon nitride.

12. The substrate according to claim 7, wherein the layer based on comprising silicon nitride is substoichiometric.

13. The substrate according to claim 7, wherein the layer based-en comprising silicon nitride is superstoichiometric.

14. An element capable of collecting light using at least one substrate according to claim 1.

15. An element capable of collecting light, comprising a first substrate and a second substrate said first and second substrate sandwiching, between at least a first and a second conductive layer forming electrodes, at least one functional layer comprising an absorbent agent, wherein at least one of the electrodes reflects in the wavelength range extending from the ultraviolet to the near infrared, and is formed from a stack of n layers (where n≧2) defining between them at least one interface zone.

16. A process for manufacturing a according to claim 1, wherein the barrier layer and the electroconductive layer are deposited using a magnetron sputtering process.

17. The substrate according to claim 1, wherein the stack comprises 4 to 12 layers.

18. The substrate according to claim 1, wherein the stack comprises 8 layers.

19. The substrate according to claim 1, wherein the electrode is based on molybdenum at most 300 nm in thickness.

20. The substrate according to claim 1, wherein the layers forming the electrode are formed from at least a first and a second different material.
